(19) United States
(12) Patent Application Publication
(10) Pub. No.: US 2014/0291590 A1
(43) Pub. Date: Oct. 2, 2014

(54) HIGH PERFORMANCE LIGHT EMITTING DEVICES FROM IONIC TRANSITION METAL COMPLEXES

(71) Applicant: The Board of Regents of the University of Texas System, Austin, TX (US)

(72) Inventors: Jason D. Slinker, Richardson, TX (US); Shen Yulong, Plano, TX (US); Bradley J. Holliday, Austin, TX (US)

(73) Assignee: The Board of Regents of the University of Texas System, Austin, TX (US)

(21) Appl. No.: 14/229,635

(22) Filed: Mar. 28, 2014

Related U.S. Application Data
(60) Provisional application No. 61/806,123, filed on Mar. 28, 2013.

(51) Int. Cl. H01L 51/00

(52) U.S. Cl. CPC H01L 51/0085
USPC 252/519.2

(57) ABSTRACT

Embodiments of the invention are directed to single layer light-emitting electrochemical cells that are enhanced by ionic additives, and methods of manufacture. These devices exhibit high efficiency, rapid response and long lifetimes.

### CROSS-REFERENCES TO RELATED APPLICATIONS

This Application claims the benefit under 35 U.S.C. §119(e) of U.S. Provisional Patent Application No. 61/806,123 filed Mar. 28, 2013 which is incorporated herein by reference in its entirety as if fully set forth herein.

### FIELD OF THE INVENTION

Embodiments of the invention are directed to single layer light-emitting electrochemical cells that are enhanced by ionic additives, and these devices exhibit high efficiency, rapid response and long lifetimes.

Other embodiments of the invention are directed to methods of manufacture of single layer light-emitting electrochemical cells.

### BACKGROUND OF THE INVENTION

Organic light-emitting diodes (OLEDs) have emerged as a viable technology for displays and high efficiency lighting applications. However, for lighting, a hindrance to their implementation arises due to the cost to manufacture the many layers needed to achieve efficient charge injection, charge transport, and recombination. A promising approach is to begin with materials that are solution processable and function efficiently in single-layer devices.

Light-emitting electrochemical cells (LEECs), which are devices consisting of a single mixed conducting layer between two electrodes, are efficient solution-processable devices. LEECs can be formed from a blend of polymers and salts or directly from ionic small molecules generalized by the term ionic transition metal complexes (iTMCs), which have produced devices with high efficiencies of up to 40 lumens per Watt (Lm/W) and with half-lives of 1000 h and beyond. These iTMCs have also been incorporated into novel architectures, such as scalable, fault-tolerant lighting panels and electroluminescent nanofibers. However, to this point, iTMC devices have not yet operated at levels sufficient for lighting applications, over 1000 cd/m², with long operational lifetimes. Furthermore, long lifetime iTMC devices have either come at the cost of long turn on times or complicated driving schemes. Thus, it would be desirable to create a light emitting device that possesses superior illumination properties without the disadvantages of existing devices.

### SUMMARY OF THE INVENTION

An embodiment of the invention is directed to a single layer LEEC enhanced by ionic additives with various cationic radii which represents a general and simplistic approach to enhanced performance. These devices exhibit high efficiency, rapid response, and long lifetimes at 3000 cd/m² and above, luminance levels appropriate for lighting.

An embodiment of the invention is directed to a simple fabrication of iTMC devices with long lifetimes at high luminance levels through the incorporation of hexafluorophosphate salts. Luminance, efficiency, and response time are improved with minimal impact on device lifetime by reducing the cation radii of the salt additives. This approach is extremely simple and, as it is generally compatible with iTMCs, it complements parallel efforts to improve these emitters. These results can be understood from the impact of ionic space charge on balancing carrier injection.

### BRIEF DESCRIPTION OF THE DRAWINGS

FIG. 1 shows an Illustration of the redistribution of ions under an applied bias for a pristine iTMC device (left) or an iTMC device blended with a salt (right) in accordance with an embodiment of the invention;

FIG. 2A shows a graph of voltage versus time for ITO/PEDOT/(Iridium complex+salt)/LiF/Al devices under 1.5 mA constant current driving. FIG. 2B shows a graph of luminance and current efficiency versus time for ITO/PEDOT/(Iridium complex+salt)/LiF/Al devices under 1.5 mA constant current driving. The type of cation is varied and held at a doping ratio of 0.1%. Salts were of the form (Cation)[PF₆];

FIG. 3 shows a graph of luminance versus time for a pristine [Ir(ppy)₂(bpy)][PF₆] cast from either an unheated solution or a solution heated at 65° C. for 10 minutes; and

FIG. 4 shows a graph of luminance versus time for an ITO/PEDOT/(Iridium complex+0.33%/wt Li[PF6])/LiF/Al device, as compared to a pristine device, under constant current driving. In this device, the solution bearing the complex and salt was heated for 10 min at 65° C. to encourage ionic dissociation.

### DETAILED DESCRIPTION OF EXEMPLARY EMBODIMENTS

An embodiment of the invention is directed to a light emitting device comprising an electroluminescent material that is solution processable and a salt additive. In certain embodiments, the salt additive is selected from the group consisting of ammonium salts, potassium salts and lithium salts.

In an embodiment of the invention, the electroluminescent material is an ionic transition metal complex (iTMC) or a transition metal coordination compound. In certain embodiments, the iTMC comprises transition metal ions and ligands.

In an embodiment of the invention, the transition metal ion possesses electroluminescent properties. In certain embodiments of the invention, the transition metal ion is iridium.

An embodiment of the claimed invention is directed to a light emitting device (LED) comprising an electroluminescent material that is solution processable and a salt additive. In certain embodiments the concentration of the salt additive ranges from 0.00001 wt % to 50 wt %. In other embodiments of the invention, the electroluminescent material is an ionic transition metal complex (iTMC) or a transition metal coordination compound. In further embodiments, the iTMC comprises transition metal ions and ligands.

In certain embodiments, the transition metal ion possesses electroluminescent properties and is selected from the group consisting of one or more of iridium, ruthenium, osmium, platinum, erbium, europium, aluminium, rhodium, palladium, tungsten and or rhenium. In further embodiments, the salt additive is selected from the group consisting of one or more of ammonium salts, potassium salts, lithium salts, beryllium salts, sodium salts, magnesium salts, calcium salts, cesium salts, rubidium salts, strontium salts and/or mercury salts. In certain embodiments, the salt additive includes anions such as fluoride, chloride, bromide, iodide, tetrafluoroborate, hexafluorophosphate , perchlorate, trifluoromethanesulfonate, bis(trifluoromethane)sulfonamide, acetate, iodate, iodoacetate, metaborate, nitrate, phosphate, phosphate monobasic, sulfate, and trifluoroacetate or any combination of these mixtures thereof.

An embodiment of the claimed invention is directed to a method of forming a light emitting device (LED), comprising: providing providing an electroluminescent material, wherein the electroluminescent material is solution processable; providing providing a salt additive; and providing a heat treatment to a mixture of the electroluminescent material and the salt additive. In certain embodiments, the method comprises adding a solvent into the mixture. In further embodiments, the heat treatment is performed at between about 65° C. and 100° C.

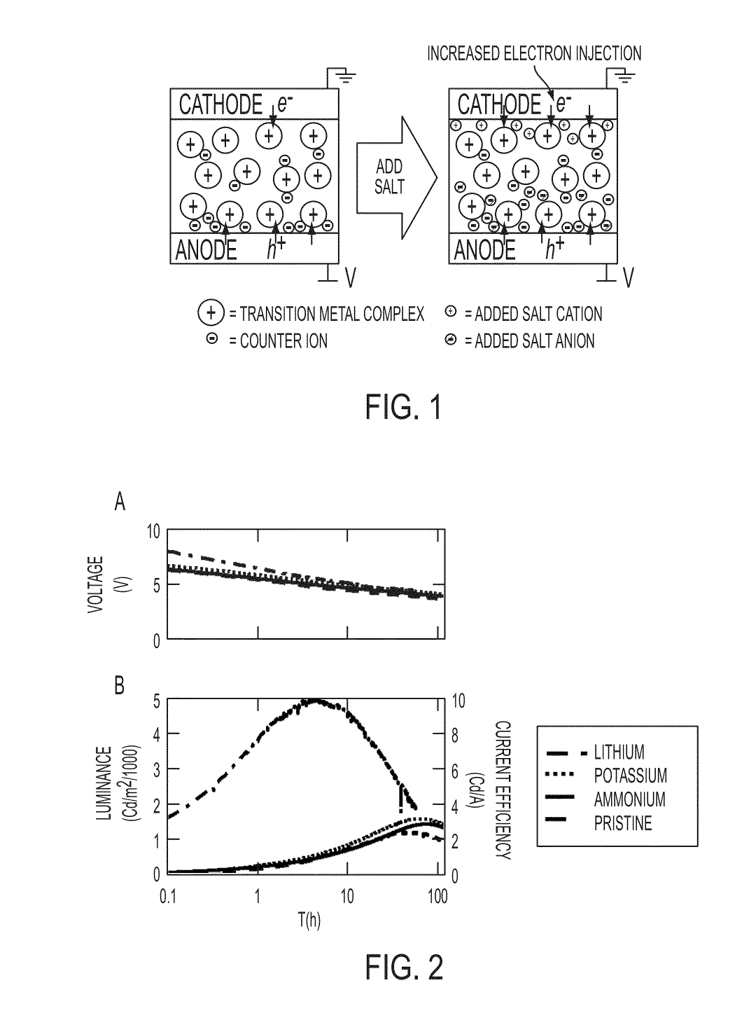

LEECs can be formed from a blend of polymers and salts or directly from ionic small molecules, such as the transition metal complex bis-(2-phenylpyridyl)-2,2′-bipyridyl iridium(III) hexafluorophosphate, [Ir(ppy)₂(bpy)][PF₆]. FIG. 1 illustrates an embodiment of the invention. A standard, pristine iTMC device has cationic complexes balanced by negatively charged counterions that are typically of much smaller size. For the particular case of a pristine film of [Ir(ppy)₂(bpy)][PF₆], the [Ir(ppy)₂(bpy)] cationic complex is 12.6 Å in diameter, whereas the [PF₆] counterion is 3.2 Å in diameter. Thus, the complexes themselves are primarily stationary under an applied bias, while the counterions are mobile.

A problem with traditional LEECs is that the density of cations at the cathode will be much lower than the density of anions at the anode for pristine devices, leading to lower electric fields at the cathode. This is a problematic development as the barrier to electron injection is often substantial, particularly when air-stable electrodes are used. However the use of salts with smaller cations added to the active layer of the device, creates a greater density of space charge at the cathode. By adding salts with cations of varied size and [PF₆] anions, as [PF₆] is the typical anion paired with iTMCs does not affect anion packing density. It is anticipated that adding salts with small and highly mobile cations will induce higher electric fields at the cathode, leading to faster device response, more balanced carrier injection, higher absolute current and luminance, and higher efficiencies. The effect will depend strongly on the cationic radii of the salts, due to the packing efficiency at the contact.

Previous studies have followed the influence of ionic additives, but none have systematically studied cation accumulation at the cathode. Conventional polymer LEECs typically rely on a mixture of poly(ethylene oxide) (PEO) and an associated salt, such as Li[O₃SCF₃]. PEO and Li[O₃SCF₃] were studied together with anionic ruthenium iTMCs as an emitter, and devices were found to have fast turn on times at 20 s Likewise, a Li[O₃SCF₃] and crown ether blend was added to binuclear ruthenium iTMCs to reduce turn on time. But these two methods produced devices with extremely low quantum efficiencies, 0.02% and lower, due in part to the choice of emitter. Several studies investigated change of the anion associated with cationic ruthenium complexes, and changing [PF₆]⁻ to [ClO₄]⁻ or [BF₄]⁻ led to a reduction of the turn-on time from several minutes to seconds. However, these experiments showed that a reduction of the turn-on time was also accompanied by an increase in the rate of degradation of the electroluminescence over time. Ionic ligands have also been utilized, bringing about a reduced turn-on time but also displaying a concomitant loss of lifetime and lower efficiencies. The ionic liquid 1-butyl-3-methylimidazolium hexafluorophosphate, [BMIM][PF₆], was added directly to iridium iTMCs and found to reduce turn-on times modestly with less dramatic impact on lifetime. Nonetheless, an approach to reducing turn-on times without compromising device stability is needed.

The phosphorescent, cationic, heteroleptic iridium(III) complex, [Ir(ppy)₂(bpy)][PF₆], was synthesized according to slight modifications of literature procedures. The composition and purity were confirmed by ¹H NMR spectroscopy, ESI mass spectometry, and combustion analysis with the measured values showing excellent agreement with either those previously reported (NMR) or expected theoretical values (MS and EA). Additionally, the photophysical properties of the complex were recorded and carefully compared to literature values. This included a determination of the UV-vis absorption profile, molar absorptivity (ε), and emission profile both in solution and in the solid-state. All recorded data were completely consistent with literature values.

Salts were purchased from Sigma Aldrich in the highest available purity and used as received. Prepatterned ITO glass substrates were purchased from Thin Film Devices, Anaheim, Calif. ITO substrates were cleaned with a nonionic detergent and water bath, followed by UV Ozone treatment. PEDOT:PSS (Clevios AI 4083) solutions were filtered through a 0.45 μm filter and then spin coated onto ITO substrates. Devices were subsequently transferred into a glove box for further processing and characterization. [Ir(ppy)₂(bpy)][PF₆] and salts of varying weight percentages were dissolved at 24 mg/mL in degassed acetonitrile inside a dry nitrogen glovebox. Solutions were passed through a 0.1 μm nylon filter prior to spin coating. Some films were prepared by heating the iTMC and salt solution on a hotplate at 65° C. while stirring for 10 minutes and allowing the solution to cool before spinning. The iTMC with salt films were spin cast at 900 rpm and thermally annealed at 120° C. for 1 h. Then samples were transferred to a vacuum chamber, where 10 Å of LiF and 800 Å of Al were deposited through a shadow mask that defined 12 devices per substrate, each with a 3 mm² active area.

The electrical characteristics were obtained with a 760D electrochemical analyzer from CH Instruments (Austin, Tex.). Radiant flux measurements were obtained with a Labsphere integrating sphere with a thermoelectric cooled silicon photodetector and Keithley 6485 Picoammeter. Electroluminescence spectra were measured with an Ocean Optics Jazz fiber spectrometer.

Electroluminescent devices of the form ITO/PEDOT/[Ir(ppy)₂(bpy)][PF₆]+salt additive/LiF/Al were fabricated and tested under 1.5 mA constant current driving (10 V compliance), and the results for various cations at 0.1%/wt are given in FIG. 2, with a full summary of device characteristics provided in Table 1. In all cases, the drive voltage starts near 6-8V, and slowly decreases with time as device resistance decreases. The luminance of the pristine device is noteworthy, with a maximum near 1200 cd/m², significantly brighter than earlier reports of long-lasting iTMC devices. Furthermore, for the luminance and current efficiency, there is an enhancement of the maximal values that follows the cationic identity of the additives in the order pristine<ammonium<potassium<lithium. This is an inverse relationship to the primary cationic radii rᵢₒₙ for each device, as r_{complex}=6.3 Å>r_{NH4}=1.43 Å>r_{K}=1.33 Å>r_{Li}=0.87 Å. While the changes for the ammonium and potassium additives are significant, on the order of 10-20% enhancements, the enhancement upon addition of lithium is drastic, raising the maximum luminance over fourfold to nearly 5000 cd/m², well beyond the DOE benchmark for solid state lighting sources. Likewise, all maximum efficiency metrics are improved by factors of 3-4 upon Li salt addition: the current efficiency reaches 9.9 cd/A, the power efficiency improves to 5.8 Lm/W, and the quantum efficiency increases to 3.2% photons per electron.

It is important to consider lifetime along with the luminance for each of these devices. For the pristine, ammonium, and potassium-enhanced devices, times to maximum radiant flux (tₒₙ) and from tₒₙ to ½ of radiant flux (t_{1/2}) vary from 50-80 h and 170-300 h, respectively. The Li device shows a 10-fold improved tₒₙ of 4.6 h and a t_{1/2} of 40 h. While this latter figure is lower than ultimately desired, this is still well beyond any figure reported for iTMC devices operating at levels appropriate for lighting applications. One figure of merit for iTMC performance is the total emitted energy over a 3 mm² device, Eₜₒₜ, taken by integrating the radiant flux from the application of a bias up to the point where light emission decays to ⅕ of its maximum value. This number gives a quantitative simultaneous measure of radiant flux and lifetime. The Eₜₒₜ of these devices vary from 18-55 J, essentially equal to the best iTMC devices to date, which notably are run at much lower luminances. (Related to this figure, the total emitted energy density Uₜₒₜ is also reported and is calculated by dividing Eₜₒₜ by the active area. Uₜₒₜ serves as a better benchmark as it is irrespective of emitter size.) Thus, these high luminance devices are not achieved at the expense of overall emitter stability, as the devices maintain the same energetic output as the state of the art in the field operating at much lower luminance levels. Also, it is important to note that these exceptional performance values are attained with a simple, unoptimized complex, [Ir(ppy)₂(bpy)][PF₆], so greater values may be in store for iTMC emitters with higher photoluminescent quantum yields.

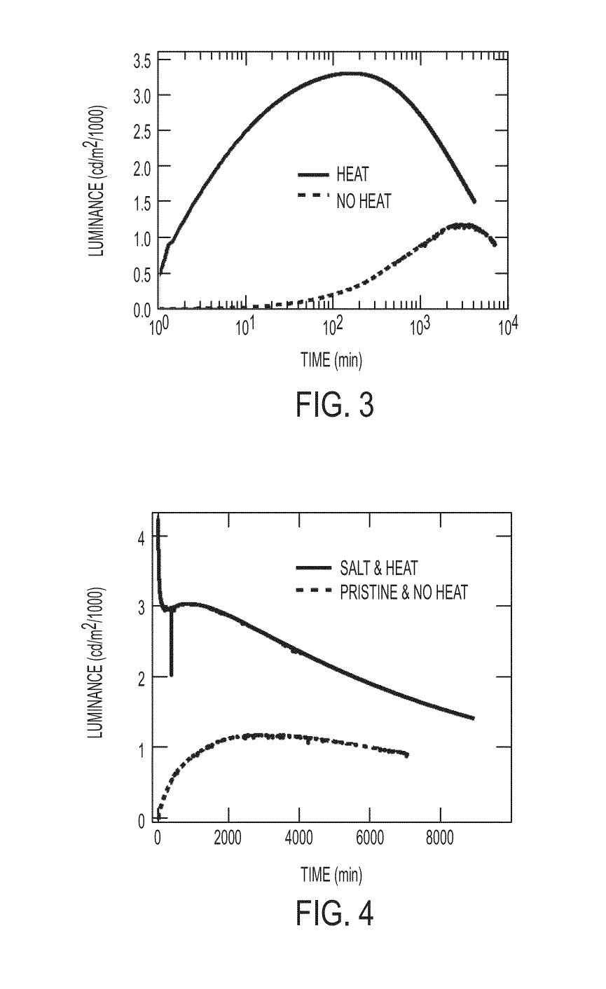

Additionally, it is possible to observe luminance and response time enhancement of similar order with pristine iTMC devices through heat processing. The bond between anions and cations can be strong, so complete ionization may not be occurring in the devices noted above. Contributing to this effect, as-cast pristine iTMC films have been shown to crystallize with intermediate-range order: for ruthenium iTMCs, this is on the order of about three iTMC lattice constants. These crystals may lock in ionic structure and discourage ionic redistribution. To encourage destruction of crystal domains and greater dissociation of the salt additives, a device was prepared by heating the acetonitrile/iTMC solution at 65° C. for 10 min just prior to spin coating. FIG. 3 shows an [Ir(ppy)₂(bpy)][PF₆] LEEC prepared in this way operating under constant current driving (1.5 mA, 10V compliance) as compared to the standard pristine device prepared without solution heating. Luminance is improved to 3300 cd/m², turn on time is reduced from 2 days to 2.5 h, and external quantum efficiency is raised to 2.4%. Thus, heat processing improves device metrics to a similar degree as is achieved with lithium salt additives.

It has been found that the combination of lithium addition and heat processing of the solution can enable extremely fast device turn on under conventional constant current driving while maintaining long lifetimes and high luminance levels. Up to this point, long lifetime iTMC devices have come at the expense of long turn on times or complex driving schemes. FIG. 4 shows the voltage and luminance versus time for devices with lithium salt additives and solution heat processing versus a pristine, unheated standard. The device with a combination of Li ions and heat turned on in 10 seconds. The luminance followed by a brief period of transient response at high brightness and subsequent stable operation at a luminance maximum of 3000 cd/m². From this time forward, this device exhibits a t_{1/2} of 137 h and a high luminance. It has been reported that iTMCs operating under static driving exhibit t_{1/2}/tₒₙ ratios of typically 1-10, indicating a tradeoff between lifetime and turn on time, and only pulsed driving circumvents this. However, in this case, the lifetime is clearly not compromised: t_{1/2}/tₒₙ is 50000. Likewise, other performance metrics (Table 1) are improved relative to the pristine device, including current efficiency (6.0 cd/A), external quantum efficiency (2.0%) and total emitted energy (Eₜₒₜ=33.8 J, Uₜₒₜ=11.3 J/mm²). Table 1 shows the response time, lifetime, brightness, and efficiency characteristics of ITO/PEDOT/[Ir(ppy)₂(bpy)][PF₆]+additive/LiF/Al devices, for 0.1%/wt additives.

TABLE 1

| | | | | | Current | Power | Quantum | Luminance |
|---|---|---|---|---|---|---|---|---|
| | tₒₙ^{a} | t_{1/2}^{b} | Eₜₒₜ^{c} | Uₜₒₜ^{d} | Efficiency | Efficiency | Efficiency | Maximum |
| Additive | [h] | [h] | [J] | [J/mm²] | [cd/A] | [Lm/W] | [ph/el, %] | [cd] |
| None | 49 | 167 | 34.5^{e} | 11.5^{e} | 2.4 | 1.9 | 0.77 | 1180 |
| [NH₄][PF₆] | 77 | 199 | 32.1^{e} | 10.7^{e} | 2.8 | 2.2 | 0.92 | 1410 |
| K[PF₆] | 63 | 295 | 55.4^{e} | 18.5^{e} | 3.1 | 2.3 | 1.01 | 1560 |
| Li[PF₆] | 4.6 | 37 | 18.2 | 6.1 | 9.9 | 5.8 | 3.21 | 4950 |
| Li[PF₆]^{f} | 0.0028 | 137 | 33.8 | 11.3 | 6.0 | 5.8 | 1.97 | 3030 |

^{a}Time from application of current to maximum radiant flux.
^{b}Time from tₒₙ to ½ of radiant flux maximum.
^{c}Total emitted energy, calculated by integrating the radiant flux curve from the application of current to the time for the radiant flux to decay to ⅕ of maximum. Measured from a 3 mm² device.
^{d}Total emitted energy density, calculated by dividing Eₜₒₜ by the device active area.
^{e}Extrapolated values, assuming first order exponential decay of the radiant flux.
^{f}Device cast from a solution that was heated at 65° C. for 10 minutes. 0.33%/wt salt.

from a 3 mm² device. [d] Total emitted energy density, calculated by dividing Eₜₒₜ by the device active area. [e] Extrapolated values, assuming first order exponential decay of the radiant flux. [f] Device cast from a solution that was heated at 65° C. for 10 minutes. 0.33%/wt salt.

Efficient light emission is dictated by balanced carrier injection, and the hole and electron currents are strongly dependent on ionic redistribution. Currently, iTMC device operation is described either in terms of the electrodynamic model or an electrochemical model of operation, and both models now claim ionic double-layer formation occurs at the electrodes, consistent with multiple reports of electric force microscopy in LEEC devices. As a result of these ionic space charge effects at the electrodes, deMello³⁷ has shown that the electron and hole current densities j_{e,h} follow:

$${j}_{e , h} = - \frac{{AE}_{e , h}^{2}}{{Δφ}_{e , h}} exp ( \frac{- 8 π \sqrt{2 em}}{3 h} \frac{Δ {φ}_{e , h}^{3 / 2}}{{E}_{e , h}} ) \qquad ( 1 )$$

where A is a proportionality constant allowing for backflow, e is the elementary charge, m is the electron mass, h is Planck's constant, E_{e,h} is the electric field at the cathode and anode, respectively, and ΔΦ_{e/h} are the barrier heights to charge injection at the cathode and anode, respectively. This is the expression for tunneling injection through a triangular energy barrier. For high electric fields, the exponential term tends to one. This simplifies the current densities to:

$${j}_{e , h} \approx - \frac{{AE}_{e , h}^{2}}{Δ {φ}_{e , h}} , {E}_{e , h} >> 0 , \qquad ( 2 )$$

showing that the carrier current densities depend on the square of the interfacial electric fields at the electrodes. Recent work with iTMC devices has shown that the current tends towards E² dependence as high electric fields develop at the electrodes. Thus, the current through the device and subsequent light emission is strongly influenced by the magnitude of the interfacial fields, which in turn strongly depend on the ionic concentration at the interface. A Helmholtz layer of square densely-packed ions at the electrode supports a potential drop ΔΦ given by:

$$ΔΦ = \frac{e}{{r}_{ion} {ɛ}_{0} {ɛ}_{r}} \qquad ( 3 )$$

where rᵢₒₙ is the radius of the ion, ε₀ is the permittivity of free space, and εᵣ is the dielectric constant of the semiconductor film. Thus, for this dense arrangement of ions, the potential drop is inversely proportional to ionic radius. In our case, rᵢₒₙ varies from 6.3 Å for [Ir(ppy)₂(bpy)]⁺ to 0.68 Å for Li⁺. Ions such as lithium can support potential drops of tens of volts for modest dielectric values. This extreme case of a densely packed monolayer of ions is not realized in a practical device, but this illustrates the strong influence of cationic radius on the interfacial fields.

The current findings would suggest that efficient electron injection is difficult to obtain under typical pristine Ir iTMC device operation. The strong trend of increasing performance with smaller cations suggest that interfacial packing of the ions at the contacts is critical, and the results with heat processing point to the need for efficient ionic dissociation redistribution, potentially governed by film morphology. Lithium cations in particular possess the size and mobility to bring about more balanced hole and electron concentrations in these devices.

While particular embodiments of the present disclosure have been illustrated and described, it would be obvious to those skilled in the art that various other changes and modifications can be made without departing from the spirit and scope of the disclosure. It is therefore intended to cover in the appended claims all such changes and modifications that are with the scope of this disclosure.

What is claimed is:

1. A light emitting device (LED) comprising an electroluminescent material that is solution processable and a salt additive.

2. The device of claim 1, wherein the concentration of the salt additive ranges from 0.00001 wt % to 50 wt %.

3. The device of claim 1, wherein the electroluminescent material is an ionic transition metal complex (iTMC) or a transition metal coordination compound.

4. The device of claim 2, wherein the iTMC comprises transition metal ions and ligands.

5. The device of claim 3, wherein the transition metal ion possesses electroluminescent properties.

6. The device of claim 4, wherein the transition metal ion is selected from the group consisting of one or more of iridium, ruthenium, osmium, platinum, erbium, europium, aluminium, rhodium, palladium, tungsten or rhenium.

7. The device of claim 1, wherein the salt additive is selected from the group consisting of one or more of ammonium salts, potassium salts, lithium salts, beryllium salts, sodium salts, magnesium salts, calcium salts, cesium salts, rubidium salts, strontium salts or mercury salts.

8. The device of claim 1, wherein the salt additive includes fluoride, chloride, bromide, iodide, tetrafluoroborate, hexafluorophosphate , perchlorate, trifluoromethanesulfonate, bis(trifluoromethane)sulfonamide, acetate, iodate, iodoacetate, metaborate, nitrate, phosphate, phosphate monobasic, sulfate, and trifluoroacetate or mixtures thereof.

9. A method of forming a light emitting device (LED), comprising:
providing an electroluminescent material, wherein the electroluminescent material is solution processable;
providing a salt additive; and
providing heat treatment a mixture of the electroluminescent material and the salt additive.

10. The method of claim 9, further comprising adding a solvent into the mixture.

11. The method of claim 9, wherein the mixture is a solution.

12. The method of claim 9, wherein the heat treatment is performed at between about 65° C. and 100° C.
